(19) United States
(12) Patent Application Publication
(10) Pub. No.: US 2019/0229031 A1
(43) Pub. Date: Jul. 25, 2019

(54) SEMICONDUCTOR DEVICE AND METHOD OF MANUFACTURING THEREOF

(71) Applicant: Mitsubishi Electric Corporation, Tokyo (JP)

(72) Inventors: Takuya TAKAHASHI, Tokyo (JP); Yoshitaka OTSUBO, Tokyo (JP); Hiroyuki MASUMOTO, Tokyo (JP)

(73) Assignee: Mitsubishi Electric Corporation, Tokyo (JP)

(21) Appl. No.: 16/181,793

(22) Filed: Nov. 6, 2018

(30) Foreign Application Priority Data
Jan. 23, 2018 (JP) 2018-008917

(51) Int. Cl. H01L 23/367; H01L 23/053; H01L 23/31; H01L 23/00; H01L 21/52; H01L 21/56

(52) U.S. Cl. CPC H01L 23/3675; H01L 23/053; H01L 23/3107; H01L 24/45; H01L 21/52; H01L 2224/48225; H01L 2924/10272; H01L 2924/1033; H01L 2924/1037; H01L 2924/10375; H01L 2924/10254; H01L 21/565

(57) ABSTRACT

The object of the technique disclosed in the specification is to provide a technique in which the production cost is reduced without impairing the mechanical strength of the resin, and the heat radiation is improved. The semiconductor device relates to the technique disclosed in the specification includes an insulating substrate, a semiconductor element disposed on an upper surface of the insulating substrate, a case connected to the insulating substrate, such that the semiconductor element is accommodated inside thereof, and resin filled inside of the case, such that the semiconductor element is embedded, on the upper surface of the resin in the inside of the case, a first concave part is formed, the first concave part is formed at a position covering an entire of the semiconductor element in plan view.

### BACKGROUND OF THE INVENTION

### Field of the Invention

The technique disclosed in the specification relates to, for example, a power semiconductor device.

### Description of the Background Art

In the power module of the related art, sealing with a direct potting resin (DP resin) may be required, in that case, an internal electrode is needed to be sealed with the DP resin up to the uppermost surface thereof (see Japanese patent application Laid-Open No, 2016-58563, for example).

Also, in the power module of the related art, a sealing resin may be partially filled for stress reduction (see Japanese patent application Laid-Open No. 64-18247 (1989), for example).

In the power semiconductor device disclosed in Japanese patent application Laid-Open No. 2016-58563, the internal electrode is needed to be sealed with the DP resin up to the uppermost surface thereof, therefore, the resin is filled into areas in which the resin is not required to be filled, consequently, the production cost increases.

Meanwhile, in a case where the resin surrounding of the semiconductor element is reduced as disclosed in Japanese patent application Laid-Open No. 64-18247 (1989), the thickness of the resin above the semiconductor element is large, therefore, heat conduction from the semiconductor element to the surface of the resin is low, consequently, the heat radiation is unsatisfactory. Also, forming of a groove surrounding the semiconductor element deforms the shape of resin, and consequently, impairs the mechanical strength of the resin in a projection.

### SUMMARY

The object of the technique disclosed in the specification is to provide a technique in which the production cost is reduced without impairing the mechanical strength of the resin, and the heat radiation is improved.

The first aspect of the technique disclosed in the specification includes an insulating substrate, a semiconductor element disposed on an upper surface of the insulating substrate, a case connected to the insulating substrate, such that the semiconductor element is accommodated inside thereof, and resin filled inside of the case, such that the semiconductor element is embedded. On the upper surface of the resin in the inside of the case, a first concave part is formed, the first concave part is formed at a position covering an entire of the semiconductor element in plan view.

The second aspect of the technique disclosed in the specification includes filling resin inside of a case accommodating a semiconductor element such that the semiconductor element disposed on an upper surface of an insulating substrate is embedded, on an upper surface of the resin that is filled, disposing a metal mold for the resin, performing thermosetting treatment on the resin with the metal mold being disposed, and removing the metal mold after the thermosetting treatment, on the upper surface of the resin, a first concave part is formed, and the first concave part is formed at a position covering an entire of the semiconductor element in plan view.

According to the first and second aspects of the techniques disclosed in the specification, the distance between the semiconductor element and the upper surface of the resin is shortened, therefore, heat is effectively conducted to the upper surface of the resin when the semiconductor element generates heat, thus the heat radiation to the ambient air is improved. Also, the first concave part is formed above the semiconductor element and no projection and so forth is formed in the resin, therefore, the production cost is reduced without impairing the mechanical strength of the resin.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view schematically illustrating an example of a configuration of a semiconductor device according to Embodiment;

FIG. 2 is a cross-sectional view schematically illustrating an example of a configuration of a semiconductor device according to Embodiment;

FIG. 3 is a plan view illustrating the configuration of the semiconductor device according to the Embodiment illustrated in FIG. 2 as an example; and

FIG. 4 is a cross-sectional view schematically illustrating an example of a configuration of a semiconductor device according to Embodiment.

### DESCRIPTION OF THE PREFERRED EMBODIMENTS

Hereinafter, Embodiments are described with reference to the accompanying drawings.

It should be noted that the drawings are schematically illustrated and, therefore, the configuration is, appropriately omitted or simplified for facilitating the description. Also, the mutual relationship between the sizes and positions of the configurations and so forth respectively illustrated in the different drawings is not necessarily precise and can be appropriately changed.

In addition, in the following description, the same components are denoted by the same reference numerals, and the names and functions thereof are also similar. Therefore, detailed description thereof may be omitted to avoid redundancy.

Also, in the following description, even when terms indicating a specific position and direction such as “upper”, “lower”, “left”, “right”, “side”, “bottom”, “front” or “rear” are stated, the terms are used to facilitate understanding of Embodiments for convenience, and therefore, irrelevant to directions in practical implementation.

Further, in the following description, even when ordinal numbers such as “first” or “second” are stated, the terms are used to facilitate understanding of Embodiments, and therefore, the usage of the ordinal umbers does not limit the indication of the ordinal numbers to ordering.

### Embodiment 1

Hereinafter, a semiconductor device and a method of manufacturing the semiconductor device according to Embodiment are described.

### Configuration of Semiconductor Device

FIG. 1 is a cross-sectional view schematically illustrating an example of a configuration of a semiconductor device according to Embodiment. As illustrated in FIG. 1, the semiconductor device includes an insulating substrate 12, a semiconductor element 14 disposed on the upper surface of the insulating substrate 12 with solder 22 interposed therebetween, and a case 16 connected to the insulating substrate 12, such that the semiconductor element 14 is accommodated inside thereof, with an adhesive 18 interposed therebetween, and a DP resin 20 filled such that the semiconductor element 14 is embedded inside of the case 16.

The insulating substrate 12 includes an insulating plate 12A, an electrode pattern 12B and an electrode pattern 12D provided on the upper surface of the insulating plate 12A, and an electrode pattern 12C provided on the lower surface of the insulating plate 12A. In addition, in the case 16, an electrode 16A and an electrode 16B are formed on the inner surface thereof in which the semiconductor element 14 is accommodated.

The electrode pattern 12B of the insulating substrate 12 and the electrode 16A of the case 16 are electrically connected via a wiring 24A. The electrode pattern 12D of the insulating substrate 12 and the electrode 16B of the case 16 are electrically connected via a wiring 24B. The semiconductor element 14 and the electrode pattern 12D are electrically connected via a wiring 26. The wiring 26, the wiring 24A, and the wiring 24B each are embedded in the DP resin 20.

As illustrated in FIG. 1, the uppermost surface of the DP resin 20 is located above the wiring 24A, the wiring 24B, and the wiring 26. A concave part 200 is formed on the uppermost surface of the DP resin 20. The concave part 200 is located above the semiconductor element 14, therefore, the thickness of the DP resin 20 facing the upper surface of the semiconductor element 14 is formed to be thinner than in the case where the concave part 200 is not formed. Also, a part of the uppermost surface of the DP resin 20, which is close to the case 16, is located higher than a part of the uppermost surface of the DP resin 20, which is formed on the upper surface of the semiconductor element 14, that is, the upper surface on which the concave part 200 is formed. It should be noted that the concave part 200 is formed at a position covering the entire semiconductor element 14 in plan view. That is, the semiconductor element 14 is positioned inside the concave part 200 in plan view.

According to such a configuration, the thickness of the DP resin 20 facing the upper surface of the semiconductor element 14 is formed to be thinner than in the case where the concave part 200 is not formed. Therefore, forming the concave part 200 shortens the distance between the semiconductor element 14 and the uppermost surface of the DP resin 20, thereby the temperature rise on the uppermost surface of the DP resin 20 is promoted, and the performance of radiating the heat of the semiconductor element 14 to the ambient air is improved.

Further, the amount of the DP resin 20 on the upper surface of the semiconductor element 14 decreases, therefore, production cost is reduced. Deformation in the form of the DP resin 20 is not caused, that is, no projection and so forth is formed in the DP resin 20, therefore, the mechanical strength is not impaired.

### Embodiment 2

A semiconductor device and a method of manufacturing the semiconductor device according to Embodiment are described, In the following description, the same components described in above Embodiment are illustrated in the drawings with the same reference numerals, and detailed description thereof is appropriately omitted.

### Configuration of Semiconductor Device

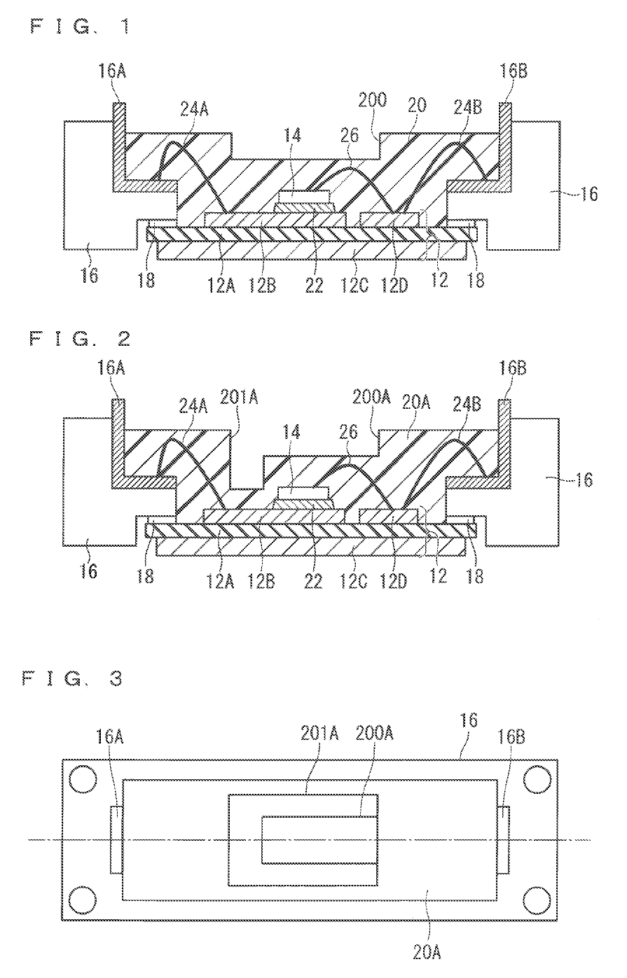

FIG. 2 is a cross-sectional view schematically illustrating art example of a configuration of a semiconductor device according to Embodiment. As illustrated in FIG. 2, the semiconductor device includes the insulating substrate 12, the semiconductor element 14, the case 16, and a DP resin 20A. FIG. 3 is a plan view illustrating the configuration of the semiconductor device according to Embodiment illustrated in FIG. 2 as an example.

As illustrated in FIGS. 2 and 3, a concave part 200A and a concave part 201A are formed on the uppermost surface of the DP resin 20A.

The concave part 200A is located above the semiconductor element 14, therefore, the thickness of the DP resin 20A facing the upper surface of the semiconductor element 14 is formed to be thinner than in the case where the concave part 200A is not formed. It should be noted that the concave part 200A is formed at a position covering the entire semiconductor element 14 in plan view.

The concave part 201A is a concave part further formed on the bottom surface of the concave part 200A. Therefore, the concave part 201A is formed deeper than the concave part 200A. Further, the concave part 201A is, in plan view, formed so as to surround at least a part of the periphery of the semiconductor element 14, therefore, the thickness of the DP resin 20A located at periphery of the semiconductor element 14 is formed to be thinner than in the case where the concave part 201A is not formed.

According to such a configuration, the thickness of the DP resin 20A facing the upper surface of the semiconductor element 14 is formed to be thinner than in the case where the concave part 200A is not formed. Therefore, forming the concave part 200A shortens the distance between the semiconductor element 14 and the uppermost surface of the DP resin 20A, thereby the temperature rise on the uppermost surface of the DP resin 20A is promoted, and the performance of radiating the heat of the semiconductor element 14 to the ambient air is improved.

Further, the amount of the DP resin 20A that is not in the region where the semiconductor element 14, the wiring 24A, the wiring 24B, and so forth are sealed therewith decreases, therefore, production cost is effectively reduced. Moreover, forming the concave part 200A and the concave part 201A increases the surface area of the DP resin 20A, therefore, heat radiation to the ambient air is improved. Also, the amount of the required DP resin 20A decreases, therefore, the original amount of resin is applicable to larger substrate components.

### Embodiment 3

A semiconductor device and a method of manufacturing the semiconductor device according to Embodiment are described. In the following description, the same components in above-described Embodiments are illustrated in the drawings with the same reference numerals, and detailed description thereof is appropriately omitted.

### Configuration of Semiconductor Device

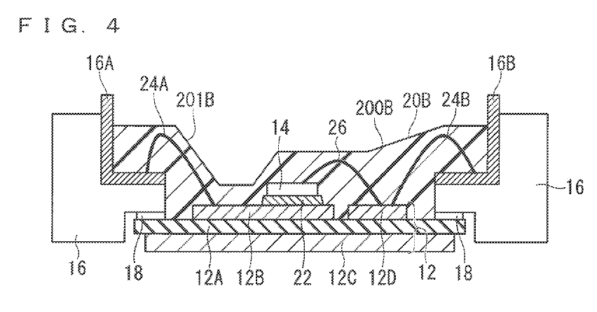

FIG. 4 is a cross-sectional view schematically illustrating an example of a configuration of a semiconductor device according to Embodiment. As illustrated in FIG. 4, the semiconductor device includes the insulating substrate 12, the semiconductor element 14, the case 16, and a DP resin 20B.

As illustrated in FIG. 4, a concave part 200B and a concave part 201B are formed on the uppermost surface of the DP resin 20B.

The concave part 200B is a concave part having a tapered side surface. The concave part 200B is located above the semiconductor element 14, therefore, the thickness of the DP resin 20B facing the upper surface of the semiconductor element 14 is formed to be thinner than in the case where the concave part 200B is not formed. It should be noted that the concave part 200B is formed at a position covering the entire semiconductor element 14 in plan view.

The concave part 200B is a concave part having a tapered side surface. The concave part 201B is formed deeper than the concave part 200B. Further, the concave part 201B is, in plan view, formed so as to surround at least a part of the periphery of the semiconductor element 14, therefore, the thickness of the DP resin 20B located at periphery of the semiconductor element 14 is formed to be thinner than in the ease where the concave part 201B is not formed.

According to such a configuration, forming the DP resin 20B so as to follow the curved shapes of wirings and so forth, therefore, the amount of the DP resin 20B that is not in the region where the semiconductor element 14, the wiring 24A, the wiring 24B, and so forth are sealed therewith effectively decreases.

It should be noted that, in the above configuration, the concave part 200B may be replaced with a configuration in which the side surface and the bottom surface intersect perpendicularly to each other as with the concave part 200A illustrated in FIG. 2, or the concave part 201B may be replaced with a configuration in which the side surface and the bottom surface intersect perpendicularly to each other as with the concave part 201A illustrated in FIG. 2.

### Embodiment 4

A semiconductor device and a method of manufacturing the semiconductor device according to Embodiment are described. In the following description, the same components in above-described Embodiments are illustrated in the drawings with the same reference numerals, and detailed description thereof is appropriately omitted.

### Configuration of Semiconductor Device

In the semiconductor device according to Embodiments 1 to 3, uncured DP resin is potted in a case 16. And the semiconductor element 14 is embedded into the DP resin.

Thereafter, on the upper surface of the DP resin filled in the case 16, a mold subjected to metal plating using metal having low adhesion to the DP resin, such as Ni-plating is placed. And the DP resin is subjected further to curing, that is, thermosetting treatment, to be cured. When the DP resin is cured, the mold placed on the upper surface of the DP resin is removed.

In the semiconductor device illustrated in Embodiments 1 to 3, deformation in the form of resin is not caused, that is, no projection and so forth is formed, also, a part of the uppermost surface of the resin, which is close to the case 16 is located higher than a part of the uppermost surface of the resin, which is formed on the upper surface of the semiconductor element 14, therefore the mold placed on the upper surface of the DP resin is readily removed.

### Embodiment 5

A semiconductor device and a method of manufacturing the semiconductor device according to Embodiment are described in the following description, the same components in above-described Embodiments are illustrated in the drawings with the same reference numerals, and detailed description thereof is appropriately omitted.

### Configuration of Semiconductor Device

In the semiconductor device according to Embodiments 1 to 3, uncured DP resin is potted in a case 16. Thereafter, on the upper surface of the DP resin filled in the case 16, a mold subjected to metal plating using metal having low adhesion to the DP resin, such as Ni-plating is placed. And the DP resin is subjected further to curing, that is, thermosetting treatment, to be cured. When the DP resin is cured, the mold placed on the upper surface of the DP resin is removed.

Here, metal used for a mold to be placed on the upper surface of the DP resin includes metal having a higher linear thermal expansion coefficient than the DP resin.

When the curing is performed at a high temperature, and the above-stated mold is removed after cooling, the mold contracts than the DP resin due to the high linear thermal expansion coefficient. Thus the mold is readily removed.

### Embodiment 6

A semiconductor device and a method of manufacturing the semiconductor device according to Embodiment are described. In the following description, the same components in above-described Embodiments are illustrated in the drawings with the same reference numerals, and detailed description thereof is appropriately omitted.

### Configuration of Semiconductor Device

The semiconductor device according to Embodiment includes the semiconductor device described in any of above Embodiments, and uses, as a material of a semiconductor element 14, a wide-gap semiconductor, such as silicon carbide (SiC).

SiC is a type of wide-gap semiconductors. A wide-gap generally refers to a semiconductor having a bandgap of about 2 eV or more, and group III nitride including gallium nitride (GaN), group H oxide including zinc oxide (ZnO), group II chalcogenide including zinc sclenide (ZnSe), diamond, and silicon carbide are known as materials. The case of using silicon carbide is described in Embodiment 6, however, other semiconductor and wide gap semiconductors are similarly applied.

According to such a configuration, when the calorific value of the semiconductor element 14 is high, the surface temperature of the DP resin also increases, therefore heat radiation is improved.

### Effects of Above-Described Embodiments

Next, examples of effects of above-described Embodiments are described. It should be noted that, in the following description, effects are described based on the specific configurations illustrated in the above described Embodiments, however, other specific configurations may be applied in place of the configurations illustrated in the specification, within the scope of producing the similar effects.

Also, the replacement may be implemented with a plurality of Embodiments. That is, each of the configurations illustrated in the corresponding Embodiments may be combined one another to produce the similar effects.

According to Embodiments described above, the semiconductor device includes an insulating substrate 12, a semiconductor element 14, a case 16, and a resin. Here, the resin corresponds to at least one of a DP resin 20, a DP resin 20A, and a DP resin 20B, for example. The semiconductor element 14 is disposed on the upper surface of the insulating substrate 12. The case 16 is connected to the insulating substrate 12, such that the semiconductor element 14 is accommodated inside thereof. The DP resin 20 is filled inside of the case 16 such that the 4 is embedded. And, on the upper surface of the DP resin 20 in the inside of the case 16, a first concave part is formed. Here, the first concave part corresponds to at least one of a concave part 200, a concave part 200A, and a concave part 200B. The concave part 200 is formed at a position covering the entire semiconductor element 14 in plan view.

According to such a configuration, the distance between the semiconductor element 14 and the upper surface of the DP resin 20 is shortened, therefore, heat is effectively conducted to the upper surface of the DP resin 20 when the semiconductor element 14 generates heat, thus the heat radiation to the ambient air is improved. Also, the concave part is formed above the semiconductor element 14 and no projection and so forth is formed in the DP resin 20, therefore, the production cost is reduced without impairing the mechanical strength of the DP resin 20.

It should be noted that the description of the other configurations other than the configurations illustrated in the specification is appropriately omitted. That is, as long as the described configurations are provided, the above described effects can be produced.

However, even in the case where at least one of the other configurations other than the configurations illustrated in the specification is appropriately added to the configuration described above, that is, other configurations other than the configurations illustrated in the specification, which are not referred to as configurations described above are appropriately added, the similar effects can be produced.

Further, according to Embodiments described above, at least one wiring electrically connected to the semiconductor element 14 is provided. Here, the wiring corresponds to at least one of a wiring 26, a wiring 24A, and a wiring 24B, for example. Also, the DP resin 20 is filled such that the wiring 26, the wiring 24A, and the wiring 24B are embedded. According to such a configuration, in the resin, a concave part formed above the semiconductor element 14 is formed and the wiring connected to the semiconductor element 14 is embedded, therefore, the production cost is reduced while improving the heat radiation.

Further, according to Embodiments described above, a second concave part formed on the bottom surface of the concave part 200A is provided. Here, the second concave part corresponds to a concave part 201A, for example. According to such a configuration, forming the concave part 201A decreases the amount of the DP resin 20A that is not in the region where the semiconductor element 14, the wiring 24A, the wiring 24B, and so forth are sealed therewith, therefore, production cost is effectively reduced. Moreover, forming the concave part 200A and the concave part 201A increases the surface area of the DP resin 20A, therefore, heat radiation to the ambient air is improved.

Further, According to Embodiments described above, at least one of the concave part 200B and the concave part 201B has a tapered side surface. According to such a configuration, forming the DP resin 20B so as to follow the curved shapes of wirings and so forth, therefore, the amount of the DP resin 20B that is not in the region where the semiconductor element 14, the wiring 24A, the wiring 24B, and so forth are sealed therewith effectively decreases. The surface area of the DP resin 20B increases, therefore, the heat radiation to the ambient air is improved. Also, the amount of the required DP resin 20B decreases, therefore, the original amount of resin is applicable to larger substrate components.

Further, According to Embodiments described above, the semiconductor element 14 is formed of a wide-gap including SiC. According to such a configuration, when the calorific value of the semiconductor element 14 is high, the surface temperature of the DP resin also increases, therefore heat radiation is improved.

According to Embodiments described above, in the method of manufacturing the semiconductor device, the DP resin 20 is filled inside of the case 16 accommodating the semiconductor element 14 disposed on the upper surface of the insulating substrate 12, such that the semiconductor element 14 is embedded. And, on the upper surface of the filled DP resin 20, a metal mold for the DP resin 20 is disposed. And, the DP resin 20 with the metal mold being disposed is subjected to thermosetting treatment. The metal mold is, then, removed after the thermosetting treatment. And, on the upper surface of the DP resin 20, a concave part 200 is formed. The concave part 200 is formed at a position covering the entire semiconductor clement 14 in plan view.

According to such a configuration, the distance between the semiconductor element 14 and the upper surface of the DP resin 20 is shortened, therefore, heat is effectively conducted to the upper surface of the DP resin 20 when the semiconductor element 14 generates heat, thus the heat radiation to the ambient air is improved. Also, the concave part is formed above the semiconductor element 14, and no projection and so forth is formed in the DP resin 20, therefore, the production cost is reduced without impairing the mechanical strength of the DP resin 20.

It should be noted that the description of the other configurations other than the configurations illustrated in the specification is appropriately omitted. That is, as long as the described configurations are provided, the above described effects can be produced.

However, even in the case where at least one of the other configurations other than the configurations illustrated in the specification is appropriately added to the configuration described above, that is, other configurations other than the configurations illustrated in the specification, which are not referred to as configurations described above are appropriately added, the similar effects can be produced.

Further, the order of implementation of the respective processes can be changed, unless otherwise specified.

Also, according to Embodiments described above, the metal mold is subjected to Ni-plating. According to such a configuration, the adhesion between the metal mold and the DP resin is low, therefore, the metal mold is readily removed from the DP resin.

Also, according to Embodiments described above, the metal mold is made of metal having a higher linear thermal expansion coefficient than the resin. According to such a configuration, when the curing is performed at a high temperature, and the above-stated mold is removed after cooling, the mold contracts than the DP resin due to the high linear thermal expansion coefficient, Thus the mold is readily removed.

### Modification of Embodiments described above

In Embodiments described above, materials, material properties, dimensions, shapes, relative arrangement relations, conditions for implementation, and so forth for the respective components may be described, however, these represent a mare example in all aspects, and are not limited to the description in the specification.

Accordingly, it is understood that numerous other modifications variations, and equivalents can be devised without departing from the scope of the invention. For example, the following cases where at least one of the components is to be modified, added, or omitted, further, at least one of the components of at least one of Embodiments is extracted and then combined with components of other Embodiment, are involved.

Also, the descriptions in the specification are referred for the every object related to the technique, and the descriptions each are not regarded as conventional techniques.

Further, in above-described Embodiments, when names of materials are stated unless otherwise specified, an alloy of the material and other additives, and so forth are included, so far as consistent with Embodiments.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
an insulating substrate;
a semiconductor element disposed on an upper surface of the insulating substrate;
a case connected to the insulating substrate, such that the semiconductor element is accommodated inside thereof; and
resin filled inside of the case, such that the semiconductor element is embedded, wherein
on the upper surface of the resin in the inside of the case, a first concave part is formed, and
the first concave part is formed at a position covering an entire of the semiconductor element in plan view.

2. The semiconductor device according to claim 1, further comprising:
at least one wiring electrically connected to the semiconductor element, wherein the resin is filled such that the at least one wiring is embedded.

3. The semiconductor device according to claim 1, further comprising:
a second concave part is formed on a bottom surface of the first concave part.

4. The semiconductor device according to claim 3, wherein at least one of the first concave part and the second concave part has a tapered side surface.

5. The semiconductor device according to claim 1, wherein
the semiconductor element is formed of a wide-gap including SiC.

6. A method of manufacturing a semiconductor device, comprising:
filling resin inside of a case accommodating a semiconductor element such that the semiconductor element disposed on an upper surface of an insulating substrate is embedded;
on an upper surface of the resin that is filled, disposing a metal mold for the resin;
performing thermosetting treatment on the resin with the metal meld being disposed; and
removing the metal mold after the thermosetting treatment, wherein
on the upper surface of the resin, a first concave part is formed, and
the first concave part is formed at a position covering an entire of the semiconductor element in plan view.

7. The method of manufacturing a semiconductor device according to claim 6, wherein the metal mold is subjected to Ni-plating.

8. The method of manufacturing a semiconductor device according to claim 6, wherein the metal mold is made of metal having a higher linear thermal expansion coefficient than that of the resin.

9. The method of manufacturing a semiconductor device according to claim 6, wherein the semiconductor element is formed of a wide-gap including SiC.

10. The semiconductor device according to claim 2, wherein
a second concave part is further formed on a bottom surface of the first concave part.

11. The semiconductor device according to claim 2, wherein
the semiconductor element is formed of a wide-gap including SiC.

12. The semiconductor device according to claim 3, wherein
the semiconductor element is formed of a wide-gap including SiC.

13. The semiconductor device according to claim 4, wherein
the semiconductor element is formed of a wide-gap including SiC.

14. The method of manufacturing a semiconductor device according to claim 7, wherein
the metal mold is made of metal having a higher linear thermal expansion coefficient than that of the resin.

15. The method of manufacturing a semiconductor device according to claim 7, wherein
the semiconductor element is formed of a wide-gap including SiC.

16. The method of manufacturing a semiconductor device according to claim 8, wherein
the semiconductor element is formed of a wide-gap including SiC.
